(19) United States
(12) Patent Application Publication
(10) Pub. No.: US 2016/0358892 A1
(43) Pub. Date: Dec. 8, 2016

(54) SEMICONDUCTOR PACKAGE AND METHOD FOR MANUFACTURING THE SAME

(71) Applicant: ELECTRONICS AND TELECOMMUNICATIONS RESEARCH INSTITUTE, Daejeon (KR)

(72) Inventors: Haksun LEE, Daejeon (KR); KWANG-SEONG CHOI, Daejeon (KR); Hyun-cheol BAE, Daejeon (KR); Yong Sung EOM, Daejeon (KR)

(73) Assignee: ELECTRONICS AND TELECOMMUNICATIONS RESEARCH INSTITUTE, Daejeon (KR)

(21) Appl. No.: 15/172,097

(22) Filed: Jun. 2, 2016

(30) Foreign Application Priority Data
Jun. 3, 2015 (KR) 10-2015-0078681

(51) Int. Cl. H01L 25/065; H01L 23/31; H01L 25/00; H01L 21/56; H01L 23/00

(52) U.S. Cl. CPC H01L 25/0657; H01L 21/563; H01L 24/83; H01L 25/50; H01L 24/81; H01L 24/92; H01L 24/32; H01L 24/17; H01L 24/73; H01L 23/3142; H01L 2225/06593; H01L 2225/06513; H01L 2225/06541; H01L 2224/16146; H01L 2224/32145; H01L 2224/73204; H01L 2225/06517; H01L 2224/16227; H01L 2224/32225; H01L 2224/92143; H01L 2224/83201; H01L 2224/13144; H01L 2224/13147; H01L 2224/13124; H01L 2224/8385; H01L 2224/2919; H01L 2224/2929; H01L 2224/29387; H01L 2924/0665; H01L 2924/07025; H01L 2924/05442

(57) ABSTRACT

Provided is a method for manufacturing a semiconductor package, which includes providing a first substrate, providing, over the first substrate, a second substrate including an active region in which a semiconductor element is disposed and a periphery region surrounding the active region, providing an adhesive membrane between the first and second substrates, and mounting the second substrate on the first substrate, wherein the mounting of the second substrate includes aligning the second substrate on the first substrate by using an alignment member protruding from the periphery region of the second substrate.

### CROSS-REFERENCE TO RELATED APPLICATIONS

This U.S. non-provisional patent application claims priority under 35 U.S.C. §119 of Korean Patent Application No. 10-2015-0078681, filed on Jun. 3, 2015, the entire contents of which are hereby incorporated by reference.

### BACKGROUND

The present disclosure herein relates to a semiconductor package and a method for manufacturing the same, and more particularly, to a semiconductor package for which a bonding process is performed for stacking a 3D semiconductor package and a method for manufacturing the same.

As a semiconductor device becomes high speed and high integration, the number of input and output pins rapidly increases, development of a connection technique using a through silicon via (TSV) electrode is enlarged, and development of a 3D semiconductor chip stacking structure using the same is enlarged. In particular, when a plurality of semiconductor chips are vertically stacked to realize high density chip stacking, semiconductor chips having various functions may be integrated on a small area. When semiconductor chips are stacked on an interposer or a wafer, bonding may be performed by using an adhesive film or underfill. When a bonding process is performed by using the adhesive film such as a non-conductive film (NCF), a thermal compression process is essentially accompanied. Accordingly, a processing time becomes longer and a processing efficiency may be lowered. When a bonding process using an underfill is proceeded, bubbles generated in the process may influence alignment of chips. When a compression process using a load is proceeded, the underfill may creep up to the top surface of the chip and contaminate a compression member. When a reflow process is proceeded without load, it is difficult to align the chips caused by bubble generation or an underfill flow.

### SUMMARY

The present disclosure provides a semiconductor package which has a vertical stacking structure and in which semiconductor elements may be easily aligned, and a method for manufacturing the same.

The present disclosure also provides a semiconductor package which prevents semiconductor chips from tilting caused by an underfill flow or bubble generation at the time of stacking semiconductor chips, and a method for manufacturing the same.

The objectives of the present invention are not limited to the above-described. The objectives not mentioned in the above should be clearly understood by those skilled in the art from description below.

An embodiment of the inventive concept provides a method for manufacturing a semiconductor package including: providing a first substrate; providing, over the first substrate, a second substrate including an active region in which a semiconductor element is disposed and a periphery region surrounding the active region; providing an adhesive membrane between the first and second substrates; and mounting the second substrate on the first substrate, wherein the mounting of the second substrate includes aligning the second substrate on the first substrate by using an alignment member protruding from the periphery region of the second substrate.

In an embodiment, the second substrate may include a front surface facing a top surface of the first substrate and a rear surface facing the front surface, when mounted on the first substrate, and the aligning of the second substrate may include using a first alignment member protruding from the front surface.

In an embodiment, the aligning of the second substrate may include contacting the first alignment member and a base alignment member protruding from the top surface of the first substrate each other to be aligned.

In an embodiment, the contacting of the first alignment member and the base alignment member each other to be aligned may include fixing the second substrate on the first substrate to prevent tilting or misalignment caused by a flow of the adhesive membrane.

In an embodiment, the method may further include: mounting a third substrate on the second substrate, wherein the mounting of the third substrate may include aligning the third substrate by using a second alignment member protruding from the rear surface of the second substrate.

In an embodiment, the third substrate may include a front surface facing the rear surface of the second substrate and a rear surface facing the front surface, when mounted on the second substrate, and the aligning of the third substrate may include contacting the second alignment member and a third alignment member protruding from the front surface of the third substrate each other to be aligned.

In an embodiment, the method may further include: compressing the second substrate on the rear surface of the second substrate after mounting the second substrate.

In an embodiment, the adhesive membrane may be an underfill.

In an embodiments of the inventive concept, a semiconductor package includes: a first substrate; a second substrate mounted on the first substrate and including an active region in which a semiconductor element is disposed and a periphery region surrounding the active region; an adhesive membrane configured to fill between the first and second substrates; and an alignment member protruding from the periphery region of the second substrate and configured to align the second substrate on the first substrate.

In an embodiment, the second substrate may include a front surface facing a top surface of the first substrate and a rear surface facing the front surface, when mounted on the first substrate, and the alignment member may be provided to at least one of the front surface and the rear surface.

In an embodiment, the alignment member may include: a first alignment member protruding from the front surface; and a second alignment member protruding from the rear surface.

In an embodiment, the alignment member may further include a base alignment member protruding from a top surface of the first substrate to face the first alignment member and configured to contact the first alignment member.

In an embodiment, an inner surface of the first alignment member may contact an outer surface of the base alignment member.

In an embodiment, the semiconductor package may further include: a third substrate mounted on the second substrate and including a front surface facing the rear surface of the second substrate and a rear surface facing the front surface, wherein the third substrate may further include a third alignment member protruding from the front surface and configured to contact the second alignment member to align the third substrate.

In an embodiment, the adhesive membrane may be an underfill.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIGS. 1A to 4A are cross-sectional views for explaining a method for manufacturing a semiconductor package according to an embodiment of the inventive concept;

FIGS. 1B to 4B are respective perspective views of FIGS. 1A to 4A;

FIGS. 5 to 8 are cross-sectional views schematically illustrating a process for packaging semiconductor chip structures manufactured by using the method of FIG. 4A, and FIGS. 1B to 4B; and

FIGS. 9 and 10 respectively illustrate a first semiconductor chip having alignment members according to other embodiments.

### DETAILED DESCRIPTION

Advantages and features of the present invention, and methods for achieving the same will be cleared with reference to exemplary embodiments described later in detail together with the accompanying drawings. However, the present invention is not limited to the following exemplary embodiments, but realized in various forms. In other words, the present exemplary embodiments are provided just to complete disclosure the present invention and make a person having an ordinary skill in the art understand the scope of the invention. The present invention should be defined by only the scope of the accompanying claims. Throughout this specification, like numerals refer to like elements.

The terms and words used in the following description and claims are to describe embodiments but are not limited the inventive concept. As used herein, the singular forms “a,” “an” and “the” are intended to include the plural forms as well, unless the context clearly indicates otherwise. It will be further understood that the terms “comprises” and/or “comprising” used herein specify the presence of stated components, operations and/or elements but do not preclude the presence or addition of one or more other components, operations and/or elements.

Example embodiments are described herein with reference to cross-sectional views and/or plan views that are schematic illustrations of example embodiments. In the drawings, the thicknesses of layers and regions are exaggerated for clarity. As such, variations from the shapes of the illustrations as a result, for example, of manufacturing techniques and/or tolerances, are to be expected. Thus, example embodiments should not be construed as limited to the particular shapes of regions illustrated herein but may be to include deviations in shapes that result, for example, from manufacturing. For example, an implanted region illustrated as a rectangle may, typically, have rounded or curved features. Thus, the regions illustrated in the figures are schematic in nature and their shapes may be not intended to illustrate the actual shape of a region of a device and are not intended to limit the scope of example embodiments.

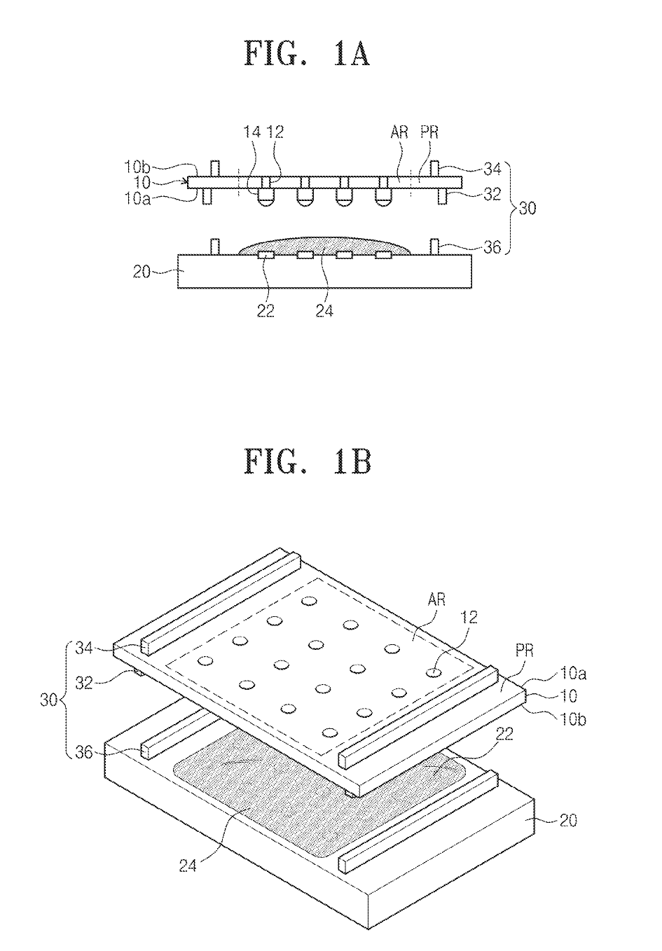

FIGS. 1A to 4A, and FIGS. 5 to 8 are cross-sectional views for explaining a method for manufacturing a semiconductor package according to an embodiment of the inventive concept. FIGS. 1B to 4B are respective perspective views of FIGS. 1A to 4A. Hereinafter, the method for manufacturing a semiconductor package according to an embodiment of the inventive concept will be described in detail with reference to FIGS. 1A to 4A, FIGS. 1B to 4B, and FIGS. 5 to 8.

Referring to FIGS. 1A and 1B, a semiconductor package may include a first substrate 10 and a second substrate 20. The first substrate 10 may be mounted on the first substrate 20. The first substrate 10 may include an active region (AR) on which memory elements are formed and a periphery region (PR) surrounding the AR. At least a part of the AR may include an integrated circuit (not illustrated). The first substrate 10 may be a semiconductor chip 10. Hereinafter, the first substrate 10 will be exemplified and described as the semiconductor chip 10. The semiconductor chip 10 may include a front surface 10a on which an integrated circuit (not illustrated) is disposed and a rear surface 10b which is an opposite surface thereto. The integrated circuit (not illustrated) may include a memory circuit, a logic circuit, or a combination thereof. When the semiconductor chip 10 is mounted on the second substrate 20, the front surface 10a may be a surface facing the top surface of the second substrate 20. The semiconductor chip 10 may include through-electrodes 12 and bumps 14. The through-electrodes 12 may be formed by using a via-first, via-middle, or via-last process. A via insulating film (not illustrated) may be provided to an external side of the plurality of through-electrodes 12 to prevent circuit elements included in the first semiconductor chip 10 from directly contacting the plurality of through-electrodes 12. The bumps 14 are formed on a front surface of the semiconductor chip 10 to be electrically connected to the through-electrodes 12. For example, the bumps 14 may electrically connect the through-electrodes 12 to bonding pads 22 on the second substrate 20. The bumps 14 may be formed with a conductive material, for example, Cu, Al, Au, or solder, etc.

The first substrate 10 may be mounted on the second substrate 20. For example, the second substrate 20 may be an interposer 20. Hereinafter, the second substrate 20 will be exemplified and described as the interposer 20. The interposer 20 may be a silicon interposer. The interposer 20 may have the same through-electrodes (not illustrated) as the semiconductor chip 10. The interposer 20 may further include the bonding pads 22 electrically connected to the stacked semiconductor chip 10. In addition, the interposer 20 may include at least one re-distribution layer (RDL) including interconnections. In addition, although not illustrated in the drawing, the interposer 20 may be connected to a carrier substrate (not illustrated) disposed therebelow. For example, the carrier substrate (not illustrated) may be a printed circuit board. At this point, the through-electrodes (not illustrated) of the interposer 20 may be electrically connected to the interconnections and bonding pads 22 to electrically connect the stacked semiconductor chip 10 and the carrier substrate (not illustrated). In addition, the through-electrodes may electrically connect a passive device such as an inductor, a capacitor, or a resistor included in the interposer 20, or a logic device such as a processor, and the stacked semiconductor chip 10 and the carrier substrate (not illustrated).

When an adhesive membrane 24 may be provided between the first substrate 10 and the second substrate 20. The adhesive membrane 24 may be provided on the second substrate 20. The adhesive membrane 24 may connect the first substrate 10 onto the second substrate 20. The adhesive membrane 24 may bond the semiconductor chip 10 onto the interposer 20. The adhesive membrane 24 may include the underfill 24. The underfill 24 may be a flowable underfill or non-flowable underfill. Hereinafter, a description will be provided about a case where the underfill 24 is exemplified as adhesive film 24. For example, the underfill 24 may include at least one of epoxy, benzocyclobutene, polyimide, a silica filler, or flux. However, the adhesive membrane 24 is not limited thereto and may be a material having various compositions.

An alignment member 30 may be provided to the semiconductor chip 10. The alignment member 30 may be disposed to protrude from the periphery region PR of the semiconductor chip 10. The alignment member 30 may include first alignment members 32 and second alignment members 34. The first alignment members 32 may protrude from the front surface 10a of the semiconductor chip 10. For example, the first alignment members 32 may vertically protrude from the front surface 10a of the semiconductor chip 10. The first alignment members 32 may be disposed on both sides of the periphery region PR. The second alignment members 34 may protrude from the rear surface 10b of the semiconductor chip 10. For example, the second alignment members 34 may vertically protrude from the front surface 10b of the semiconductor chip 10. The second alignment members 34 may be disposed on both sides of the periphery region PR. Alternatively, the alignment member 30 may further include third alignment members 36 provided on the second substrate 20. The third alignment members 36 can be referred to as a base alignment member 36. For example, the third alignment members 36 may protrude from the top surface of the interposer 20. The third alignment members 36 may vertically protrude from the top surface of the semiconductor chip 20. The third alignment members 36 may be disposed on both sides of the interposer 20, which face the periphery region PR. The third alignment members 36 may be disposed to face the first alignment members 32. For example, outer surfaces of the third alignment members 36 and inner surfaces of the first alignment members 32 contact each other, and the third alignment members 36 may be intervened and fixed between the first alignment members 32. Unlike this, inner surfaces of the third alignment members 36 and outer surfaces of the first alignment members 32 contact each other, and the first alignment members 32 may be intervened and fixed between the third alignment members 36.

The alignment members 30 may be manufactured in a silicon micro-fabrication process based on a semiconductor photolithography process. In other words, the alignment members 30 may be formed by applying a photoresist on a substrate, patterning with a mask pattern, and then proceeding a plating process. The alignment members 30 may be formed with a metal material. For example, the alignment members 30 may include Cu. However, the alignment members 30 are disposed on the periphery region PR or a region facing the periphery region PR on the second substrate 20 so as not to have an electrical influence on the semiconductor package. At this point, the alignment members 30 may have lower heights than the bumps 14. Unlike this, the alignment members 30 may have equal to or higher heights than the bumps 14. In order to adjust the heights of the alignment members 30, the number of mask patterns may be variously provided at a process for manufacturing the alignment members 30. In addition, the manufacturing method of the alignment members 30 is not limited thereto and the alignment members 30 may be formed in various methods.

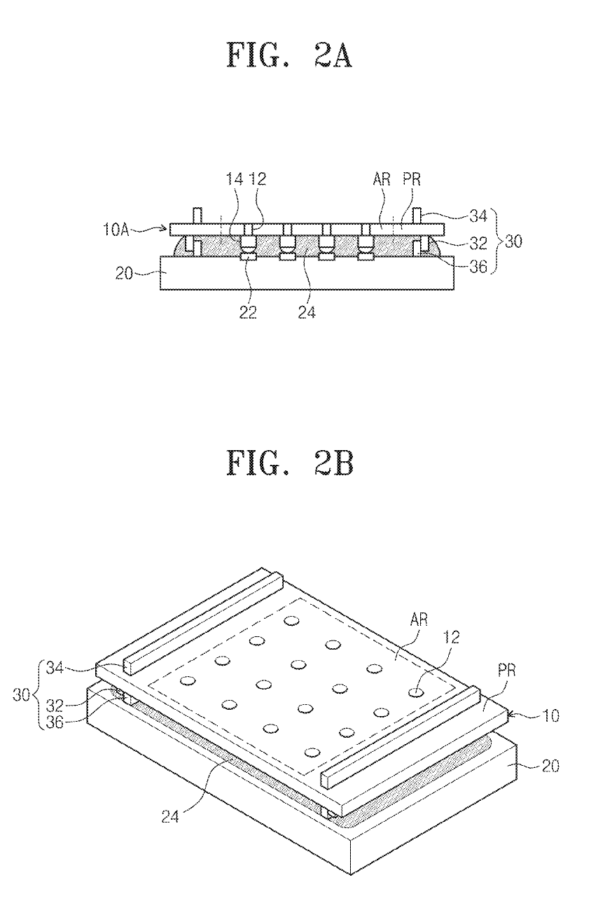

Referring to FIGS. 2A and 2B, a first semiconductor chip 10A may be stacked on the interposer 20. At this point, the third alignment members 36 on the interposer 20 and the first alignment members 32 of the first semiconductor chip 10A may contact each other and be aligned. For example, when viewed from a top portion, the third alignment members 36 are formed at an inner side than the first alignment member 32, and the outer surfaces of the third alignment members 36 and the inner surfaces of the first alignment members 32 may contact each other. Accordingly, it becomes a structure that the third alignment members 36 of the interposer 20 are forcibly intervened between the first alignment members 32 of the first semiconductor chip 10A. Unlike this, the inner surfaces of the third alignment members 36 and the outer surfaces of the first alignment members 32 contact each other, which results that the first alignment members 32 may be intervened and fixed between the third alignment members 36. Since the first semiconductor chip 10A is aligned at a precise position on the interposer 20, the bumps 14 of the first semiconductor chip 10A may be electrically connected to the bonding pads 22 of the interposer 20. The underfill 24 may cover sidewalls of the first semiconductor chip 10A, while filling a space between the first semiconductor chip 10A and the interposer 20. Since the first alignment members 32 and the third alignment members 36 physically contact, misalignment of the semiconductor chip 10 caused by a flow of the underfill 24 may be prevented. In addition, tilting of the semiconductor caused by bubble generation during processes may be prevented.

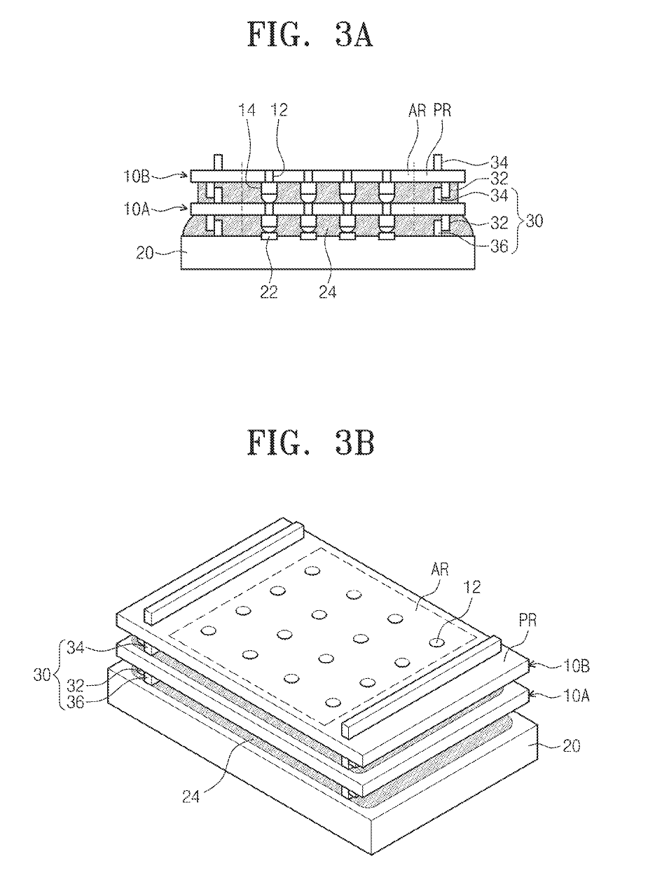

Referring to FIGS. 3A and 3B, a third substrate 10B may be mounted on the first semiconductor chip 10A. The third substrate 10B may include a semiconductor chip 10B. Hereinafter, a description will be provided about a case where the third substrate 10B is exemplified as the second semiconductor chip 10B. The second semiconductor chip 10B may have a shape and function broadly identical to or similar to the first semiconductor chip 10A. Accordingly, a description about the second semiconductor chip 10B which overlaps the foregoing will be omitted. When the second semiconductor chip 10B is stacked on the first semiconductor chip 10A, the second alignment members 34 of the first semiconductor chip 10A and the first alignment members 32 of the second semiconductor chip 10B may contact each other to align the second semiconductor chip 10B. For example, the outer surfaces of the second alignment members 34 of the first semiconductor chip 10A and the inner surfaces of the first alignment members 32 of the second semiconductor chip 10B contact each other to align the second semiconductor 10B. Accordingly, it becomes a structure that the second alignment members 34 of the first semiconductor chip 10A are forcibly intervened between the first alignment members 32 of the second semiconductor chip 10B. Since the second semiconductor chip 10B is aligned at a precise position, the bumps 14 of the second semiconductor chip 10B may be electrically connected to the through electrodes 12 of the first semiconductor chip 10A. The underfill 24 may cover sidewalls of the second semiconductor chip 10B while filling a space between the second semiconductor chip 10B and the first semiconductor chip 10A. The second alignment members 34 of the first semiconductor chip 10A and the first alignment members 32 of the second semiconductor chip 10B physically contact each other to prevent misalignment of the semiconductor chips 10A and 10B caused by a flow of the underfill 24. In addition, tilting of the semiconductor caused by bubble generation during processes may be prevented.

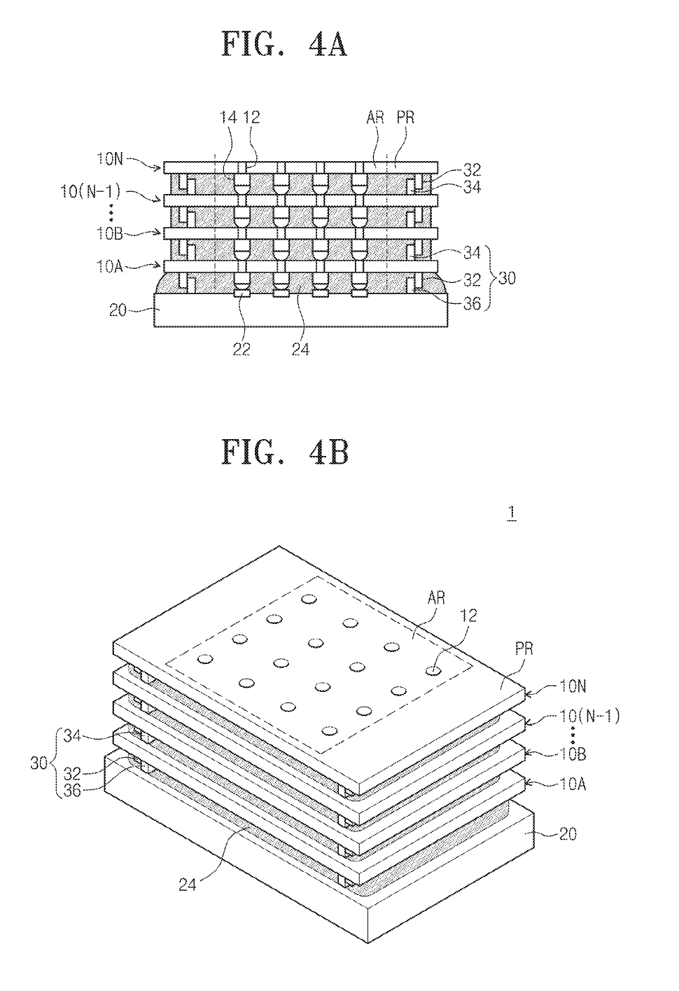

Referring FIGS. 4A and 4B, N first semiconductor chips 10A, 10B, . . . , 10(N−1), and lON are stacked to manufacture a semiconductor chip structure 1. Accordingly, the stacked N first semiconductor chips 10A, 10B, . . . , 10(N−1), and lON may be interlocked and aligned. Since the N first semiconductor chips 10A, 10B, . . . , 10(N−1), and lON are aligned at precise positions, the semiconductor chip structure 1 may be electrically connected. For example, the outer surfaces of the second alignment members 34 of the (N−1)-th semiconductor chip 10(N−1) and the inner surfaces of the first alignment members 32 of the N-th semiconductor chip lON contact each other to align the N-th semiconductor chip 10N. The underfill 24 may cover sidewalls of the N-th semiconductor chip 10N, while filling a space between the (N−1)-th semiconductor chip 10(N−1) and the N-th semiconductor chip 10N. The second alignment members 34 of the (N−1)-th semiconductor chip 10(N−1) and the first alignment members 32 of the N-th semiconductor chip lON physically contact each other to prevent misalignment of the semiconductor chips 10A, 10B, . . . , 10(N−1), and lON caused by a flow of the underfill 24. In addition, tilting of the semiconductor chips 10A, 10B, . . . , 10(N−1), and 10N caused by bubble generation during processes may be prevented. At this point, the N-th semiconductor chip 10N stacked on the top layer of the semiconductor chip structure 1 may not include only the first alignment members 32.

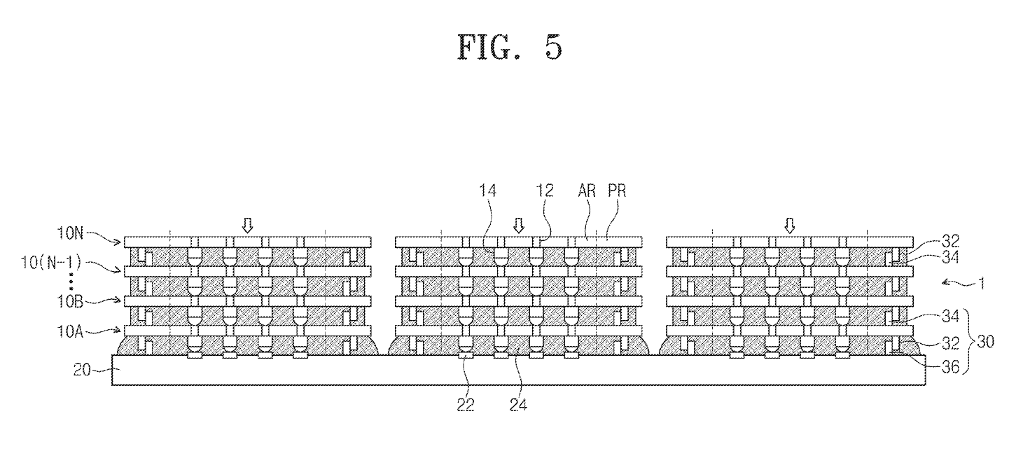

FIGS. 5 to 8 are cross-sectional views schematically illustrating a process for packaging semiconductor chip structures manufactured by using the method of FIG. 4A, and FIGS. 1B to 4B.

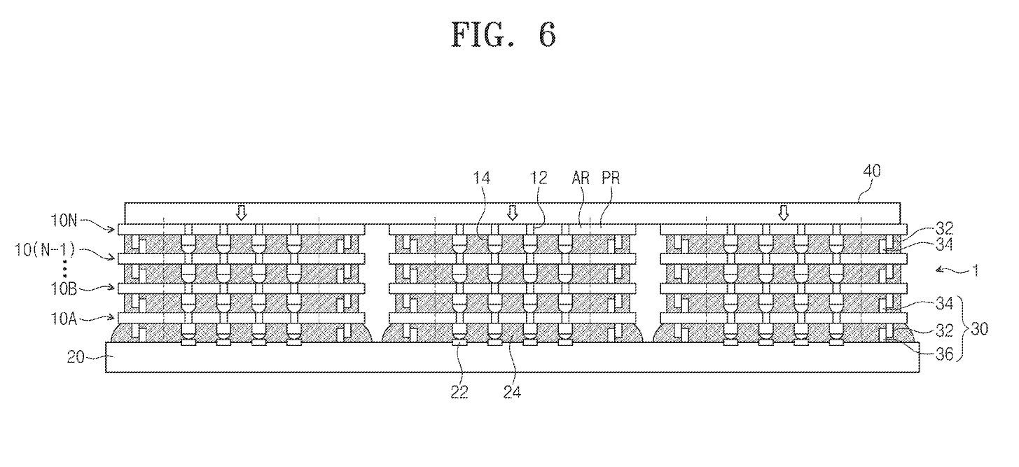

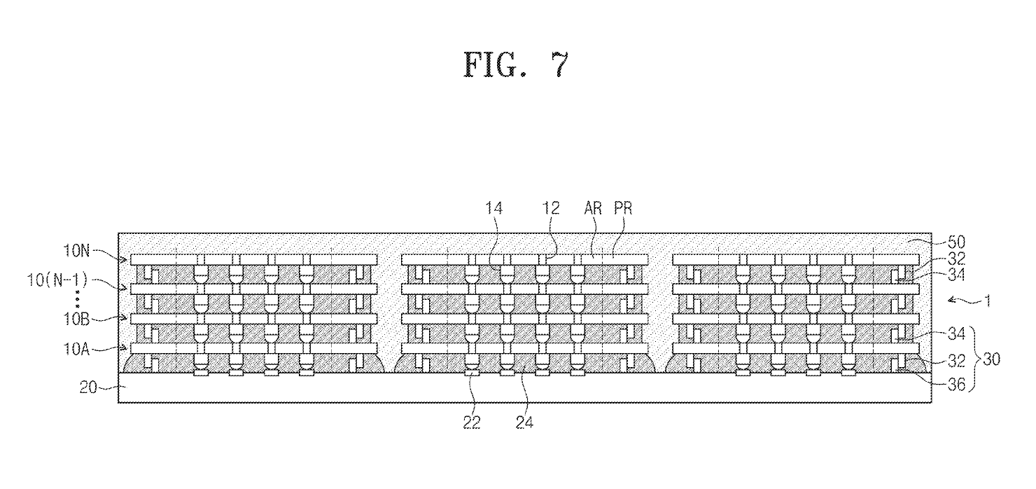

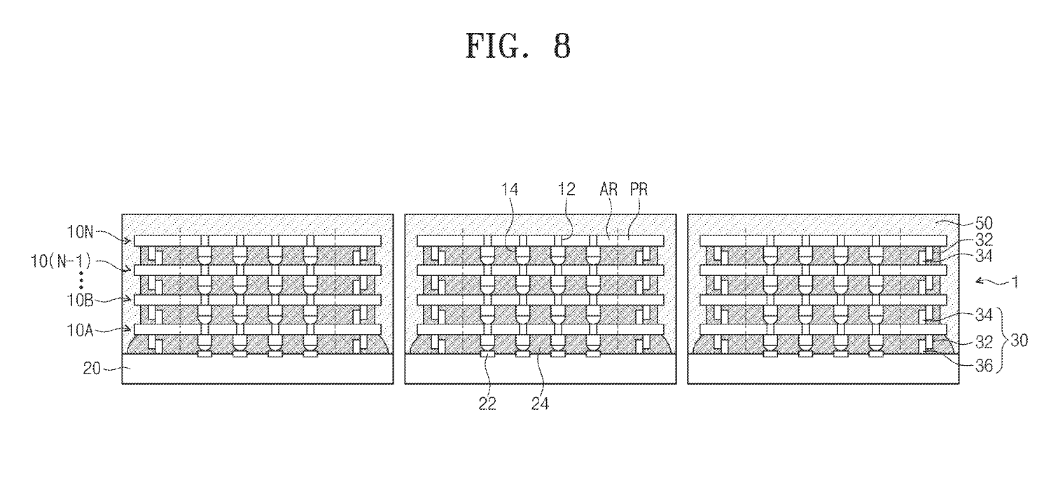

Referring to FIG. 5, a plurality of semiconductor chip structures 1 may be formed on one interposer 20. Then, referring to FIG. 6, a compression process may be proceeded by using a compression member 40. The compression member 40 may be provided to top portions of the semiconductor chip structures 1 to compress the rear surfaces 10b of the N-th semiconductor chips 10N. The compression member 40 may deliver a load to the semiconductor chip structures 1 and discharge heat to expedite a bonding process. When a process for stacking the semiconductor chip structures 1, each of which has N layers, is proceeded, the compression process using the compression member 40 may be selectively proceeded. The N-layered semiconductor chip structures 1 are entirely stacked and then the compression process may be proceeded. Alternatively, every time each semiconductor chip of the N-layered semiconductor chip structures 1 is stacked, the compression process may be proceeded. However, since the semiconductor chip structures 1 according to an embodiment of the inventive concept prevent tilting and misalignment of the semiconductor chips by the alignment members 30, a thermo-compression process is not essential and as illustrated in FIG. 6, may be simultaneously proceeded after the N-layered semiconductor chip structures 1 are entirely stacked. In addition, at the same time, a reflow process may be proceeded. Accordingly, the number of essential bonding processes is reduced to improve a throughput. Referring to FIG. 7, an encapsulation process may be proceeded for the semiconductor chip structures 1. An encapsulation 50 may include an epoxy molding compound. After the encapsulation process is completed and the encapsulation 50 is cured, as illustrated in FIG. 8, a dicing process for separating the cured encapsulation into each package may be proceeded. According, semiconductor packages may be completed.

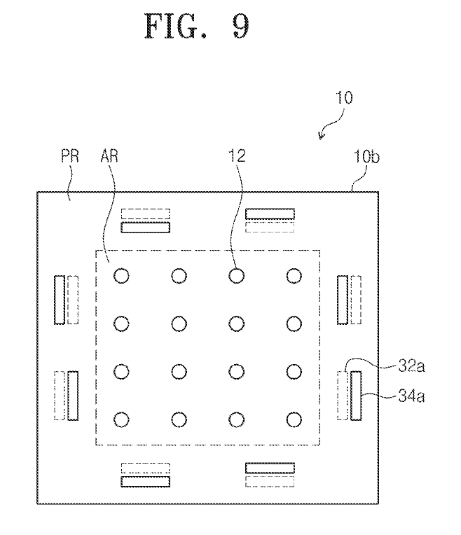

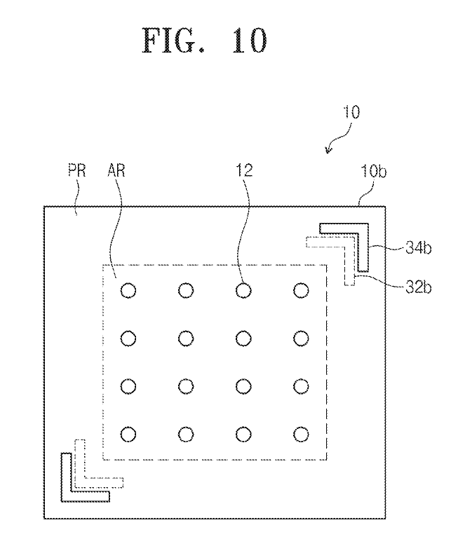

FIGS. 9 and 10 illustrate a first semiconductor chip 10 having alignment members according to different embodiments. FIGS. 9 and 10 illustrate the first semiconductor chip 10 viewed from the rear surface 10b thereof. Referring to FIG. 9, the first semiconductor chip 10 may include the first alignment member 32a and the second alignment member 34a. The first alignment member 32a and the second alignment member 34a may be formed on the periphery region PR. The first alignment member 32a is formed on the front surface 10a of the first semiconductor chip 10 and the second alignment member 34a may be formed on the rear surface 10b of the first semiconductor chip 10. At this point, the first alignment member 32a and the second alignment member 34a may be provided in plurality to be separated from each other. The first alignment member 32a and the second alignment member 34a may be separated from each other to assist smooth diffusion of the underfill 24. A plural number of the first alignment members 32a and the second alignment members 34a may be provided in a zigzag type to be deviated from a straight line. Referring to FIG. 10, the first semiconductor chip 10 may include a first alignment member 32b and a second alignment member 34b. The first alignment member 32a and the second alignment member 34a may be formed on the periphery region PR. At this point, the first alignment member 32b and the second alignment member 34b may be formed on corner sides of the periphery region PR. For example, the first alignment member 32b and the second alignment member 34b may be formed in a type to enclose the corner sides of the periphery region PR. The first alignment member 32b is formed on the front surface 10a of the first semiconductor chip 10 and the second alignment member 34b may be formed on the rear surface 10b of the first semiconductor chip 10. Since the first alignment member 32b and the second alignment member 34b are formed only on a part of the periphery region PR, the area of the periphery region PR may be reduced and accordingly a process margin may increase. Unlike this, the alignment members may have various shapes and arrangements.

In the above-described embodiments, a semiconductor package is exemplified which has the structure in which the plurality of semiconductor chips 10 are stacked on the interposer 20. However, the semiconductor package is not limited thereto and the interposer 20 may be mounted on a carrier wafer. In addition, the first substrate 10 may be various semiconductor elements other than the semiconductor chip 10, and the second substrate 20 may include various semiconductor elements other then the interposer 20. In addition, the alignment members are exemplified as formed on both sides of the semiconductor chip 10, but may be formed on only one side of the semiconductor chip 10.

In addition, in the above-described embodiments, the alignment members are exemplified as provided in a rod type, but may have various shapes.

In addition, in the above-described embodiments, a die-to-wafer (D2W) manner in which a plurality of chips are bonded on a wafer is exemplified, but the embodiments may also be applied to a wafer-to-wafer (W2W) manner in which a plurality of chips in a wafer state are boned to another wafer and to a die-to-die manner in which a chip and another chip are bonded.

According to embodiments of the inventive concept, a semiconductor package and a method for manufacturing the same may be provided which may physically support and align a plurality of semiconductor chips to prevent miss-alignment and tilting caused by bubble generation or a underfill flow, etc. during a process, when the plurality of semiconductor chips are vertically stacked.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A method for manufacturing a semiconductor package comprising:
providing a first substrate;
providing, over the first substrate, a second substrate comprising an active region in which a semiconductor device is disposed and a periphery region surrounding the active region;
providing an adhesive membrane between the first and second substrates; and
mounting the second substrate on the first substrate,
wherein the mounting the second substrate comprises aligning the second substrate on the first substrate by using an alignment member protruding from the periphery region of the second substrate.

2. The method of claim 1, wherein the second substrate comprises a front surface facing a top surface of the first substrate and a rear surface facing the front surface, when mounted on the first substrate, and
the aligning of the second substrate comprises using a first alignment member protruding from the front surface.

3. The method of claim 2, wherein the aligning of the second substrate comprises contacting the first alignment member and a base alignment member protruding from the top surface of the first substrate each other to be aligned.

4. The method of claim 3, wherein the contacting of the first alignment member and the base alignment member each other to be aligned comprises fixing the second substrate on the first substrate to prevent tilting or misalignment caused by a flow of the adhesive membrane.

5. The method according to claim 4, further comprising:
mounting a third substrate on the second substrate,
wherein the mounting the third substrate comprises aligning the third substrate by using a second alignment member protruding from the rear surface of the second substrate.

6. The method of claim 5, wherein the third substrate comprises a front surface facing the rear surface of the second substrate and a rear surface facing the front surface, when mounted on the second substrate, and
the aligning of the third substrate comprises contacting the second alignment member and a third alignment member protruding from the front surface of the third substrate each other to be aligned.

7. The method of claim 4, further comprising:
compressing the second substrate on the rear surface of the second substrate after mounting the second substrate.

8. The method of claim 1, wherein the adhesive membrane is an underfill.

9. A semiconductor package comprising:
a first substrate;
a second substrate mounted on the first substrate and comprising an active region in which a semiconductor device is disposed and a periphery region surrounding the active region;
an adhesive membrane configured to fill between the first and second substrates; and
an alignment member protruding from the periphery region of the second substrate and configured to align the second substrate on the first substrate.

10. The semiconductor package of claim 9, wherein the second substrate comprises a front surface facing a top surface of the first substrate and a rear surface facing the front surface, when mounted on the first substrate, and
the alignment member is provided to at least one of the front surface and the rear surface.

11. The semiconductor package of claim 10, wherein the alignment member comprises:
a first alignment member protruding from the front surface; and
a second alignment member protruding from the rear surface.

12. The semiconductor package of claim 11, wherein the alignment member further comprises a base alignment member protruding from a top surface of the first substrate to face the first alignment member and configured to contact the first alignment member.

13. The semiconductor package of claim 12, wherein an inner surface of the first alignment member contacts an outer surface of the base alignment member.

14. The semiconductor package of claim 11, further comprising:
a third substrate mounted on the second substrate and comprising a front surface facing the rear surface of the second substrate and a rear surface facing the front surface,
wherein the third substrate further comprises a third alignment member protruding from the front surface and configured to contact the second alignment member to align the third substrate.

15. The semiconductor package of claim 9, wherein the adhesive membrane is an underfill.
